(19) United States
(12) Patent Application Publication
(10) Pub. No.: US 2024/0244977 A1
(43) Pub. Date: Jul. 18, 2024

(54) THERMOELECTRIC MODULE

(71) Applicant: European Thermodynamics Limited, Kibworth, Leicestershire (GB)

(72) Inventors: Richard TULEY, Kibworth, Leicestershire (GB); Eleni-Chrysanthi STEFANAKI, Kibworth, Leicestershire (GB)

(21) Appl. No.: 18/559,947

(22) PCT Filed: Apr. 29, 2022
(86) PCT No.: PCT/GB2022/051105

§ 371 Date: Nov. 9, 2023

(30) Foreign Application Priority Data
May 10, 2021 (GR) 20210100315
Sep. 13, 2021 (GB) 2112997.8

(51) Int. Cl. H10N 10/82; H10N 10/01; H10N 10/17

(52) U.S. Cl. CPC H10N 10/82; H10N 10/01; H10N 10/17

(57) ABSTRACT

A thermoelectric module comprising:
a first electrically-insulating substrate having a first face and a second face opposite the first face, wherein a first plurality of electrical interconnects is disposed in a first pattern on the first face;
a second electrically-insulating substrate spaced from the first electrically-insulating substrate and having a first face facing the first face of the first electrically-insulating substrate, wherein a second plurality of electrical interconnects is disposed in a second pattern on the first face of the second electrically-insulating substrate;
a plurality of thermoelectric elements comprising n-type thermoelectric elements and p-type thermoelectric elements disposed between the first electrically-insulating substrate and the second electrically-insulating substrate, wherein each thermoelectric element extends from one of the first plurality of electrical interconnects to one of the second plurality of electrical interconnects, wherein the thermoelectric elements are arranged to form a first series-connected string of alternating n-type and p-type thermoelectric elements and a second series-connected string of alternating n-type and p-type thermoelectric elements and at least one of the n-type or p-type thermoelectric elements in the first series-connected string is electrically connected in parallel with one of the thermoelectric elements of the same type (n-type or p-type) in the second series-connected string; and
one or more regions of metallic material are disposed in a third pattern on the second face of the first electrically-insulating substrate.

The present disclosure relates to a thermoelectric module and a method of manufacture of a thermoelectric module.

Thermoelectric modules may be used as an electrically powered heat pump for temperature control including cooling and heating, or they may be used as a power generator by utilising a heat flux.

Standard thermoelectric modules have little tolerance to failure of a single part within them. For example, since the thermoelectric elements in standard thermoelectric modules are connected in series, an open circuit failure of any one element causes complete failure of the whole module. A more fault resistant module would lead to an improved reliability, lifetime and manufacturing yield.

U.S. Pat. No. 3,632,451 discloses a thermoelectric module having parallel circuits interconnected at equal potential points, each parallel circuit comprising a number of thermoelectric couples (thermocouples) connected electrically in series. This provides tolerance to failure of any one component of the circuit.

JP2002232028 discloses a thermoelectric module using parallelisation of the thermoelectric elements using the interconnects on a substrate.

WO2019132124A1 discloses a thermoelectric module using parallelisation of some series connected strings of thermoelectric elements within a module.

Standard thermoelectric modules use electrically insulating substrates which have different thermal expansion coefficients to the electrical interconnects. This can cause bowing and warping of the substrate either during its formation process, during module assembly or during operation. This can have a detrimental impact on the module yield, module lifetime and the good thermal interface required between a module and the surrounding system.

US20090025770A1 discloses a substrate which can have interconnects on one side to connect to the thermoelectric elements and a heat conductor element or fin pads on the outside. These fin pads help control the position of substrate bending that occurs due to temperature differences across the module when in operation.

In slide 11 of the conference presentation, Bartholomé K., Heuer J., Horzella J., Jägle M., König J., Tarantik K., 2014, Thermoelectric modules built with new high temperature materials, IAV 2014, Berlin, Germany, modules are disclosed with the same interconnect structure on the outer face of the substrate as on the inner face.

A first aspect provides a thermoelectric module comprising:
a first electrically-insulating substrate having a first face and a second face opposite the first face, wherein a first plurality of electrical interconnects is disposed in a first pattern on the first face;
a second electrically-insulating substrate spaced from the first electrically-insulating substrate and having a first face facing the first face of the first electrically-insulating substrate, wherein a second plurality of electrical interconnects is disposed in a second pattern on the first face of the second electrically-insulating substrate;
a plurality of thermoelectric elements comprising n-type thermoelectric elements and p-type thermoelectric elements disposed between the first electrically-insulating substrate and the second electrically-insulating substrate, wherein each thermoelectric element extends from one of the first plurality of electrical interconnects to one of the second plurality of electrical interconnects, wherein the thermoelectric elements are arranged to form a first series-connected string of alternating n-type and p-type thermoelectric elements and a second series-connected string of alternating n-type and p-type thermoelectric elements and at least one of the n-type or p-type thermoelectric elements in the first series-connected string is electrically connected in parallel with one of the thermoelectric elements of the same type (n-type or p-type) in the second series-connected string; and
one or more regions of metallic material are disposed in a third pattern on the second face of the first electrically-insulating substrate.

At least one pair of thermoelectric elements comprising a thermoelectric element in the first series-connected string and a thermoelectric element of the same type in the second series-connected string that are electrically connected in parallel may be disposed at or in the vicinity of a corner or corner region of the first electrically-insulating substrate and/or the second electrically-insulating substrate.

At least one pair of thermoelectric elements comprising a thermoelectric element in the first series-connected string and a thermoelectric element of the same type in the second series-connected string that are electrically connected in parallel may be disposed at or in the vicinity of an edge or edge region of the first electrically-insulating substrate and/or the second electrically-insulating substrate.

Every thermoelectric element in the first series-connected string may be electrically connected in parallel with one of the thermoelectric elements of the same type in the second series-connected string.

In an example implementation, not every thermoelectric element in the first series-connected string may be electrically connected in parallel with one of the thermoelectric elements of the same type in the second series-connected string. One or more of the thermoelectric elements in the first series-connected string may not be electrically connected in parallel with one of the thermoelectric elements of the same type in the second series-connected string.

For instance, up to 5%, up to 10%, up to 20%, up to 30%, up to 40%, up to 50%, up to 60%, up to 70%, up to 80%, up to 90% or up to 95% of the thermoelectric elements in the first series-connected string may each be electrically connected in parallel with one of the thermoelectric elements of the same type in the second series-connected string.

For instance, at least 5%, at least 10%, at least 20%, at least 30%, at least 40%, at least 50%, at least 60%, at least 70%, at least 80%, at least 90% or at least 95% of the thermoelectric elements in the first series-connected string may each be electrically connected in parallel with one of the thermoelectric elements of the same type in the second series-connected string.

Within the first series-connected string, there may be one or more regions where not every thermoelectric element is electrically connected in parallel with one of the thermoelectric elements of the same type in the second series-connected string, i.e. there may be one or more regions within the first series-connected string where one or more thermoelectric elements are not electrically connected in parallel with one of the thermoelectric elements of the same type in the second series-connected string. For example, there may be one or more regions within the first series-connected string where every second thermoelectric element, every third thermoelectric element, every fourth thermoelectric element, every fifth thermoelectric element or every sixth thermoelectric element is electrically connected in parallel with one of the thermoelectric elements of the same type in the second series-connected string.

The third pattern may be similar to or substantially the same as the first pattern.

The third pattern may have an area fraction on the second face of the first electrically-insulating substrate that is smaller than, the same as or larger than an area fraction of the first pattern on the first face of the first electrically-insulating substrate.

One or more regions of metallic material may be disposed in a fourth pattern on a second face opposite the first face of the second electrically-insulating substrate.

The fourth pattern may be similar to or substantially the same as the second pattern.

The fourth pattern may have an area fraction on the second face of the second electrically-insulating substrate that is smaller than, the same as or larger than an area fraction of the second pattern on the first face of the second electrically-insulating substrate.

At least one of the first plurality of electrical interconnects and/or at least one of the second plurality of electrical interconnects may be connected to two or more n-type thermoelectric elements and two or more p-type thermoelectric elements.

At least one of the first plurality of electrical interconnects and/or at least one of the second plurality of electrical interconnects may be rectangular, e.g. square, in shape, and connected to two n-type thermoelectric elements and two p-type thermoelectric elements with the thermoelectric elements being connected to the electrical interconnect(s) at or close to the corners of the rectangular, e.g. square, electrical interconnect(s).

The first substrate and/or the second substrate may be made up of two or more substrate parts.

The first substrate and/or the second substrate may be made up of at least two rows of substrate parts.

The first substrate and/or the second substrate may be made up of up to five rows of substrate parts.

The first substrate and/or the second substrate may be made up of at least two columns of substrate parts.

The first substrate and/or the second substrate may be made up of up to five columns of substrate parts.

The thermoelectric module may be connected to an external system by a mounting plate connected to the third pattern on the second surface of the first electrically-insulating substrate.

The mounting plate may comprise or may be a part of: an item requiring heating or cooling; a thermally conductive block; or a heat transfer device such as a heat sink or a heat exchanger.

When the first electrically-insulating substrate experiences a temperature change during operation, the presence of the one or more regions of metallic material disposed in the third pattern on the second face of the first electrically-insulating substrate may help to minimise or prevent warping, e.g. bowing, by offsetting or balancing forces on the two faces of the first electrically-insulating substrate.

When the second electrically-insulating substrate experiences a temperature change during operation, the presence of the one or more regions of metallic material disposed in the fourth pattern on the second face of the second electrically-insulating substrate may help to minimise or prevent warping, e.g. bowing, by offsetting or balancing forces on the two faces of the second electrically-insulating substrate.

The presence of the third pattern can reduce bowing of the first electrically-insulating substrate due to the different thermal expansion coefficients of the first plurality of electrical interconnects and the first electrically-insulating substrate. Bowing of the first electrically-insulating substrate may be particularly well reduced in embodiments, in which the third pattern is similar to or substantially the same as the first pattern.

The presence of the fourth pattern can reduce bowing of the second electrically-insulating substrate due to the different thermal expansion coefficients of the second plurality of electrical interconnects and the second electrically-insulating substrate. Bowing of the second electrically-insulated substrate may be particularly well reduced in embodiments, in which the fourth pattern is similar to or substantially the same as the second pattern.

The first plurality of electrical interconnects occupies an area fraction of less than one of the first surface of the first electrically-insulating substrate. The first plurality of electrical interconnects may occupy an area fraction of up to 95%, up to 90% or up to 80% of the first surface of the first electrically-insulating substrate. The first plurality of electrical interconnects may occupy an area fraction of at least 10%, at least 20% or at least 30% of the first surface of the first electrically-insulating substrate.

The one or more regions of metallic material disposed in the third pattern on the second face of the first electrically-insulating substrate occupy an area fraction of less than one of the second surface of the first electrically-insulating substrate. The one or more regions of metallic material disposed in the third pattern on the second face of the first electrically-insulating substrate may occupy an area fraction of up to 95%, up to 90% or up to 80% of the second surface of the first electrically-insulating substrate. The one or more regions of metallic material disposed in the third pattern on the second face of the first electrically-insulating substrate may occupy an area fraction of at least 10%, at least 20% or at least 30% of the second surface of the first electrically-insulating substrate.

The second plurality of electrical interconnects occupies an area fraction of less than one of the first surface of the second electrically-insulating substrate. The second plurality of electrical interconnects may occupy an area fraction of up to 95%, up to 90% or up to 80% of the first surface of the second electrically-insulating substrate. The second plurality of electrical interconnects may occupy an area fraction of at least 10%, at least 20% or at least 30% of the second surface of the first electrically-insulating substrate.

The one or more regions of metallic material disposed in the fourth pattern on the second face of the second electrically-insulating substrate occupy an area fraction of less than one of the second surface of the second electrically-insulating substrate. The one or more regions of metallic material disposed in the fourth pattern on the second face of the second electrically-insulating substrate may occupy an area fraction of up to 95%, up to 90% or up to 80% of the second surface of the second electrically-insulating substrate. The one or more regions of metallic material disposed in the fourth pattern on the second face of the second electrically-insulating substrate may occupy an area fraction of at least 10%, at least 20% or at least 30% of the second surface of the second electrically-insulating substrate.

There exists a thermal interface between an outer surface of the thermoelectric module (i.e. the second face of the first electrically-insulating substrate or the second face of the second electrically-insulating substrate) and any system that it is mounted into. This thermal interface results in an additional interface thermal resistance, which can reduce system performance when the thermoelectric module is used as a thermoelectric generator or a heat pump. If one or more regions of metallic material is/are disposed on the second face of the first electrically-insulating substrate and/or the second face of the second electrically-insulating substrate with an area fraction less than one, then the area for this thermal interface is reduced. This reduction in the area for the thermal interface increases the interface thermal resistance, further reducing the system performance. Therefore, the reduction in warping, e.g. bowing, of the substrate(s) can come with a performance penalty.

The spaces around and/or between the regions of metallic material disposed in the third pattern on the second surface of the first electrically-insulating substrate may reduce the interface area between the thermoelectric module and the mounting plate. A thermal interface material such as a grease, paste, putty, pad or graphite sheet may be used to reduce the thermal interface resistance between the thermoelectric module and the mounting plate. A thermal interface material may be used to fill in the gaps between the regions of metallic material disposed in the third pattern on the second surface of the first electrically-insulating substrate, but thermal interface materials typically have a thermal conductivity much smaller than that of the first electrically-insulating substrate and the one or more regions of metallic material disposed in the third pattern on the second surface of the first electrically-insulating substrate.

Advantageously, parallelisation of the thermoelectric elements, e.g. using the electrical interconnects, may provide improved fault tolerance. Provision of one or more regions of metallic material disposed on the second face of the first electrically-insulating substrate may reduce substrate warping, e.g. bowing. This combination may therefore increase module yield, lifetime and/or performance. This combination may provide a further advantage, in that the interconnect requirements for parallelisation may significantly increase the area fraction of the interconnects on the first face of the first electrically-insulating substrate, thus reducing the penalty of the increased interface thermal resistance from the one or more regions of metallic material disposed in the third pattern on the second face of the first electrically-insulating substrate.

Each substrate present may be made from any suitable electrically insulating, thermally conductive material or combination of materials. Examples of suitable materials may include aluminium oxide, aluminium nitride, beryllium oxide, zinc oxide, silicon oxide or silicon nitride, or any combination of such materials. The thermal expansion coefficient of any substrate present may be in the range of from 2×10⁻⁶ K⁻¹ to 11×10⁻⁶ K⁻¹.

The electrical interconnects may be made of any suitable conductive material or combination of materials, which may include metals such as silver, copper or aluminium, for example. The thermal expansion coefficient of the electrical interconnects may be in the range from 14×10⁻⁶ K⁻¹ to 25×10⁻⁶ K⁻¹.

The electrical interconnects may be formed on the first and/or second substrate by direct bonding, sintering, brazing or electroless or electrolytic plating.

The thermoelectric module may be electrically connected to an external power source to provide cooling or heating, or be thermally connected across a temperature difference between the substrates to generate electrical power, for example.

Thermoelectric elements may only be connected in parallel in the areas of largest stresses, for example edges or corners.

One or more thermoelectric elements in the thermoelectric module disposed at or near a corner may be connected in parallel to an adjacent thermoelectric element of the same type.

One or more thermoelectric elements in the thermoelectric module disposed at or near an edge may be connected in parallel to an adjacent thermoelectric element of the same type.

Additional thermal stresses occur due to the thermal gradient present on the module in operation. These thermal stresses can reduce thermoelectric module lifetime, especially in thermal cycling operation. This thermal stress is larger for larger thermoelectric modules, due to the larger difference in lateral thermal expansion. Advantageously, the stresses may be reduced by forming one or more of the substrates from a plurality of smaller substrate parts.

The thermoelectric elements may comprise any suitable thermoelectric material, for example the thermoelectric elements may comprise any one or more of: bismuth telluride; bismuth selenide; antimony telluride; lead telluride; lead selenide; magnesium silicide; magnesium stannide; magnesium antimonide, magnesium bismuthide, higher manganese silicide; skutterudite materials; Half Heusler alloys; silicon-germanium and oxides. Suitable thermoelectric materials may include any binary, tertiary or quaternary compound, or any chemical composition, of the above listed elements (or any other elements), that exhibits favourable thermoelectric properties. The thermoelectric material may be crystalline or amorphous. The thermoelectric materials may also include any suitable combination of dopants and/or other additives that may alter the chemical composition and/or thermoelectric properties.

The thermoelectric elements may be joined to the interconnects by soldering, brazing, sintering, diffusion bonding, conductive adhesives or any other suitable method.

The first substrate and/or the second substrate may have a thickness of at least 0.05 mm or at least 0.1 mm.

The first substrate and/or the second substrate may have a thickness of up to 3 mm or up to 2 mm.

For example, the first substrate and/or the second substrate may have a thickness in the range of from 0.1 mm to 2 mm or in the range of from 0.3 mm to 1 mm.

The electrical interconnects may have a thickness in the range of from 0.001 mm to 2 mm. For instance, the electrical interconnects may have a thickness in the range of from 0.01 to 0.4 mm or in the range of from 0.05 mm to 0.3 mm.

The electrical interconnects may have a thickness of at least 0.01 mm, at least 0.02 mm, at least 0.05 mm or at least 0.1 mm.

The electrical interconnects may have a thickness of up to 0.2 mm, up to 0.30 mm or up to 0.4 mm.

The thermoelectric module may be a multistage or cascade module, where a third substrate is disposed between a first substrate and a second substrate, with n-type and p-type thermoelectric elements disposed between the first and third substrate and between the second and third substrate.

The thermoelectric module may comprise one or more further series-connected strings of alternating n-type and p-type thermoelectric elements.

Each series-connected string of alternating n-type and p-type thermoelectric elements may be considered to be a string of one or more electrically-connected thermocouples.

Each thermocouple includes an n-type thermoelectric element and a p-type thermoelectric element.

A further aspect provides a method of manufacturing a thermoelectric module comprising:
providing a first electrically-insulating substrate having a first face and a second face opposite the first face, wherein a first plurality of electrical interconnects is disposed in a first pattern on the first face and one or more regions of metallic material are disposed in a third pattern on the second face of the first electrically-insulating substrate;
providing a second electrically-insulating substrate having a first face, wherein a second plurality of electrical interconnects is disposed in a second pattern on the first face of the second electrically-insulating substrate;
providing a plurality of thermoelectric elements comprising n-type thermoelectric elements and p-type thermoelectric elements;
connecting a first end of each thermoelectric element to one of the first plurality of electrical interconnects;
connecting a second end of each thermoelectric element to one of the second plurality of electrical interconnects;
wherein the thermoelectric elements are arranged to form a first series-connected string of alternating n-type and p-type thermoelectric elements and a second series-connected string of alternating n-type and p-type thermoelectric elements and at least one of the n-type or p-type thermoelectric elements in the first series-connected string is electrically connected in parallel with one of the thermoelectric elements of the same type (n-type or p-type) in the second series-connected string.

The thermoelectric module may be a thermoelectric module according to an embodiment disclosed herein.

The method may comprise disposing, e.g. depositing, the first plurality of electrical interconnects in the first pattern on the first face of the first electrically-insulating substrate.

The method may comprise disposing, e.g. depositing, the one or more regions of metallic material in the third pattern on the second face of the first electrically-insulating substrate.

The method may comprise disposing, e.g. depositing, the second plurality of electrical interconnects in the second pattern on the first face of the second electrically-insulating substrate.

At least one pair of thermoelectric elements comprising a thermoelectric element in the first series-connected string and a thermoelectric element of the same type in the second series-connected string that are electrically connected in parallel may be disposed at or in the vicinity of a corner or corner region of the first electrically-insulating substrate and/or the second electrically-insulating substrate.

At least one pair of thermoelectric elements comprising a thermoelectric element in the first series-connected string and a thermoelectric element of the same type in the second series-connected string that are electrically connected in parallel may be disposed at or in the vicinity of an edge or edge region of the first electrically-insulating substrate and/or the second electrically-insulating substrate.

Every thermoelectric element in the first series-connected string may be electrically connected in parallel with one of the thermoelectric elements of the same type in the second series-connected string.

In an example implementation, not every thermoelectric element in the first series-connected string may be electrically connected in parallel with one of the thermoelectric elements of the same type in the second series-connected string. One or more of the thermoelectric elements in the first series-connected string may not be electrically connected in parallel with one of the thermoelectric elements of the same type in the second series-connected string.

For instance, up to 5%, up to 10%, up to 20%, up to 30%, up to 40%, up to 50%, up to 60%, up to 70%, up to 80%, up to 90% or up to 95% of the thermoelectric elements in the first series-connected string may each be electrically connected in parallel with one of the thermoelectric elements of the same type in the second series-connected string.

For instance, at least 5%, at least 10%, at least 20%, at least 30%, at least 40%, at least 50%, at least 60%, at least 70%, at least 80%, at least 90% or at least 95% of the thermoelectric elements in the first series-connected string may each be electrically connected in parallel with one of the thermoelectric elements of the same type in the second series-connected string.

Within the first series-connected string, there may be one or more regions where not every thermoelectric element is electrically connected in parallel with one of the thermoelectric elements of the same type in the second series-connected string, i.e. there may be one or more regions within the first series-connected string where one or more thermoelectric elements are not electrically connected in parallel with one of the thermoelectric elements of the same type in the second series-connected string. For example, there may be one or more regions within the first series-connected string where every second thermoelectric element, every third thermoelectric element, every fourth thermoelectric element, every fifth thermoelectric element or every sixth thermoelectric element is electrically connected in parallel with one of the thermoelectric elements of the same type in the second series-connected string.

The third pattern may be similar to or substantially the same as the first pattern.

The third pattern may have an area fraction on the second face of the first electrically-insulating substrate that is smaller than, the same as or larger than an area fraction of the first pattern on the first face of the first electrically-insulating substrate.

One or more regions of metallic material may be disposed in a fourth pattern on a second face opposite the first face of the second electrically-insulating substrate.

The fourth pattern may be similar to or substantially the same as the second pattern.

The fourth pattern may have an area fraction on the second face of the second electrically-insulating substrate that is smaller than, the same as or larger than an area fraction of the second pattern on the first face of the second electrically-insulating substrate.

The method may comprise disposing, e.g. depositing, the one or more regions of metallic material in the fourth pattern on the second face of the second electrically-insulating substrate.

At least one of the first plurality of electrical interconnects and/or at least one of the second plurality of electrical interconnects may be connected to two or more n-type thermoelectric elements and two or more p-type thermoelectric elements.

At least one of the first plurality of electrical interconnects and/or at least one of the second plurality of electrical interconnects may be rectangular, e.g. square, in shape, and connected to two n-type thermoelectric elements and two p-type thermoelectric elements with the thermoelectric elements being connected to the electrical interconnect(s) at or close to the corners of the rectangular, e.g. square, electrical interconnect(s).

The first substrate and/or the second substrate may be made up of two or more substrate parts.

The first substrate and/or the second substrate may be made up of at least two rows of substrate parts.

The first substrate and/or the second substrate may be made up of up to five rows of substrate parts.

The first substrate and/or the second substrate may be made up of at least two columns of substrate parts.

The first substrate and/or the second substrate may be made up of up to five columns of substrate parts.

The thermoelectric module may be connected to an external system by a mounting plate connected to the third pattern on the second surface of the first electrically-insulating substrate.

The mounting plate may comprise or may be a part of: an item requiring heating or cooling; a thermally conductive block; or a heat transfer device such as a heat sink or a heat exchanger.

When the first electrically-insulating substrate experiences a temperature change during operation, the presence of the one or more regions of metallic material disposed in the third pattern on the second face of the first electrically-insulating substrate may help to minimise or prevent warping, e.g. bowing, by offsetting or balancing forces on the two faces of the first electrically-insulating substrate.

When the second electrically-insulating substrate experiences a temperature change during operation, the presence of the one or more regions of metallic material disposed in the fourth pattern on the second face of the second electrically-insulating substrate may help to minimise or prevent warping, e.g. bowing, by offsetting or balancing forces on the two faces of the second electrically-insulating substrate.

The presence of the third pattern can reduce bowing of the first electrically-insulating substrate due to the different thermal expansion coefficients of the first plurality of electrical interconnects and the first electrically-insulating substrate. Bowing of the first electrically-insulating substrate may be particularly well reduced in embodiments, in which the third pattern is similar to or substantially the same as the first pattern.

The presence of the fourth pattern can reduce bowing of the second electrically-insulating substrate due to the different thermal expansion coefficients of the second plurality of electrical interconnects and the second electrically-insulating substrate. Bowing of the second electrically-insulated substrate may be particularly well reduced in embodiments, in which the fourth pattern is similar to or substantially the same as the second pattern.

The first plurality of electrical interconnects occupies an area fraction of less than one of the first surface of the first electrically-insulating substrate. The first plurality of electrical interconnects may occupy an area fraction of up to 95%, up to 90% or up to 80% of the first surface of the first electrically-insulating substrate. The first plurality of electrical interconnects may occupy an area fraction of at least 10%, at least 20% or at least 30% of the first surface of the first electrically-insulating substrate.

The one or more regions of metallic material disposed in the third pattern on the second face of the first electrically-insulating substrate occupy an area fraction of less than one of the second surface of the first electrically-insulating substrate. The one or more regions of metallic material disposed in the third pattern on the second face of the first electrically-insulating substrate may occupy an area fraction of up to 95%, up to 90% or up to 80% of the second surface of the first electrically-insulating substrate. The one or more regions of metallic material disposed in the third pattern on the second face of the first electrically-insulating substrate may occupy an area fraction of at least 10%, at least 20% or at least 30% of the second surface of the first electrically-insulating substrate.

The second plurality of electrical interconnects occupies an area fraction of less than one of the first surface of the second electrically-insulating substrate. The second plurality of electrical interconnects may occupy an area fraction of up to 95%, up to 90% or up to 80% of the first surface of the second electrically-insulating substrate. The second plurality of electrical interconnects may occupy an area fraction of at least 10%, at least 20% or at least 30% of the second surface of the first electrically-insulating substrate.

The one or more regions of metallic material disposed in the fourth pattern on the second face of the second electrically-insulating substrate occupy an area fraction of less than one of the second surface of the second electrically-insulating substrate. The one or more regions of metallic material disposed in the fourth pattern on the second face of the second electrically-insulating substrate may occupy an area fraction of up to 95%, up to 90% or up to 80% of the second surface of the second electrically-insulating substrate. The one or more regions of metallic material disposed in the fourth pattern on the second face of the second electrically-insulating substrate may occupy an area fraction of at least 10%, at least 20% or at least 30% of the second surface of the second electrically-insulating substrate.

There exists a thermal interface between an outer surface of the thermoelectric module (i.e. the second face of the first electrically-insulating substrate or the second face of the second electrically-insulating substrate) and any system that it is mounted into. This thermal interface results in an additional interface thermal resistance, which can reduce system performance when the thermoelectric module is used as a thermoelectric generator or a heat pump. If one or more regions of metallic material is/are disposed on the second face of the first electrically-insulating substrate and/or the second face of the second electrically-insulating substrate with an area fraction less than one, then the area for this thermal interface is reduced. This reduction in the area for the thermal interface increases the interface thermal resistance, further reducing the system performance. Therefore, the reduction in warping, e.g. bowing, of the substrate(s) can come with a performance penalty.

The spaces around and/or between the regions of metallic material disposed in the third pattern on the second surface of the first electrically-insulating substrate may reduce the interface area between the thermoelectric module and the mounting plate. A thermal interface material such as a grease, paste, putty, pad or graphite sheet may be used to reduce the thermal interface resistance between the thermoelectric module and the mounting plate. A thermal interface material may be used to fill in the gaps between the regions of metallic material disposed in the third pattern on the second surface of the first electrically-insulating substrate, but thermal interface materials typically have a thermal conductivity much smaller than that of the first electrically-insulating substrate and the one or more regions of metallic material disposed in the third pattern on the second surface of the first electrically-insulating substrate.

Advantageously, parallelisation of the thermoelectric elements, e.g. using the electrical interconnects, may provide improved fault tolerance. Provision of one or more regions of metallic material disposed on the second face of the first electrically-insulating substrate may reduce substrate warping, e.g. bowing. This combination may therefore increase module yield, lifetime and/or performance. This combination may provide a further advantage, in that the interconnect requirements for parallelisation may significantly increase the area fraction of the interconnects on the first face of the first electrically-insulating substrate, thus reducing the penalty of the increased interface thermal resistance from the one or more regions of metallic material disposed in the third pattern on the second face of the first electrically-insulating substrate.

Each substrate present may be made from any suitable electrically insulating, thermally conductive material or combination of materials. Examples of suitable materials may include aluminium oxide, aluminium nitride, beryllium oxide, zinc oxide, silicon oxide or silicon nitride, or any combination of such materials. The thermal expansion coefficient of any substrate present may be in the range of from 2×10⁻⁶ K⁻¹ to 11×10⁻⁶ K⁻¹.

The electrical interconnects may be made of any suitable conductive material or combination of materials, which may include metals such as silver, copper or aluminium, for example. The thermal expansion coefficient of the electrical interconnects may be in the range from 14×10⁻⁶ K⁻¹ to 25×10⁻⁶ K⁻¹.

The electrical interconnects may be formed on the first and/or second substrate by direct bonding, sintering, brazing or electroless or electrolytic plating.

The thermoelectric module may be electrically connected to an external power source to provide cooling or heating, or be thermally connected across a temperature difference between the substrates to generate electrical power, for example.

Thermoelectric elements may only be connected in parallel in the areas of largest stresses, for example edges or corners.

One or more thermoelectric elements in the thermoelectric module disposed at or near a corner may be connected in parallel to an adjacent thermoelectric element of the same type.

One or more thermoelectric elements in the thermoelectric module disposed at or near an edge may be connected in parallel to an adjacent thermoelectric element of the same type.

Additional thermal stresses occur due to the thermal gradient present on the module in operation. These thermal stresses can reduce thermoelectric module lifetime, especially in thermal cycling operation. This thermal stress is larger for larger thermoelectric modules, due to the larger difference in lateral thermal expansion. Advantageously, the stresses may be reduced by forming one or more of the substrates from a plurality of smaller substrate parts.

The thermoelectric elements may comprise any suitable thermoelectric material, for example the thermoelectric elements may comprise any one or more of: bismuth telluride; bismuth selenide; antimony telluride; lead telluride; lead selenide; magnesium silicide; magnesium stannide; magnesium antimonide, magnesium bismuthide, higher manganese silicide; skutterudite materials; Half Heusler alloys; silicon-germanium and oxides. Suitable thermoelectric materials may include any binary, tertiary or quaternary compound, or any chemical composition, of the above listed elements (or any other elements), that exhibits favourable thermoelectric properties. The thermoelectric material may be crystalline or amorphous. The thermoelectric materials may also include any suitable combination of dopants and/or other additives that may alter the chemical composition and/or thermoelectric properties.

The thermoelectric elements may be joined to the interconnects by soldering, brazing, sintering, diffusion bonding, conductive adhesives or any other suitable method.

The first substrate and/or the second substrate may have a thickness of at least 0.05 mm or at least 0.1 mm.

The first substrate and/or the second substrate may have a thickness of up to 3 mm or up to 2 mm.

For example, the first substrate and/or the second substrate may have a thickness in the range of from 0.1 mm to 2 mm or in the range of from 0.3 mm to 1 mm.

The electrical interconnects may have a thickness in the range of from 0.001 mm to 2 mm. For instance, the electrical interconnects may have a thickness in the range of from 0.01 to 0.4 mm or in the range of from 0.05 mm to 0.3 mm.

The electrical interconnects may have a thickness of at least 0.01 mm, at least 0.02 mm, at least 0.05 mm or at least 0.1 mm.

The electrical interconnects may have a thickness of up to 0.2 mm, up to 0.30 mm or up to 0.4 mm.

The thermoelectric module may be a multistage or cascade module, where a third substrate is disposed between a first substrate and a second substrate, with n-type and p-type thermoelectric elements disposed between the first and third substrate and between the second and third substrate.

The thermoelectric module may comprise one or more further series-connected strings of alternating n-type and p-type thermoelectric elements.

Each series-connected string of alternating n-type and p-type thermoelectric elements may be considered to be a string of one or more electrically-connected thermocouples.

Each thermocouple includes an n-type thermoelectric element and a p-type thermoelectric element.

The skilled person will appreciate that except where mutually exclusive, a feature or parameter described in relation to any one of the above aspects may be applied to any other aspect. Furthermore, except where mutually exclusive, any feature or parameter described herein may be applied to any aspect and/or combined with any other feature or parameter described herein.

Embodiments will now be described, by way of example only, with reference to the accompanying drawings, in which:

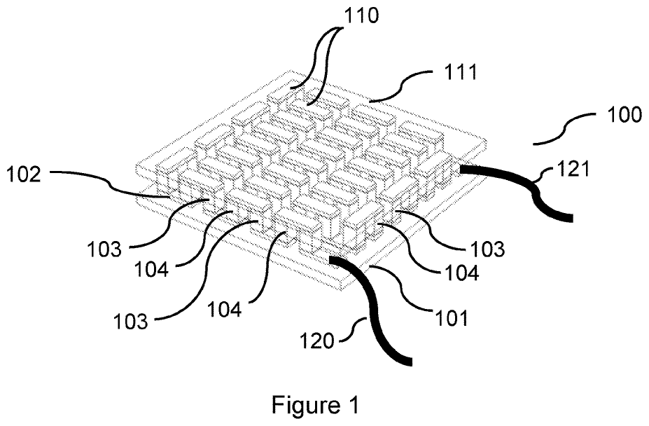

FIG. 1 is a schematic representation of a standard thermoelectric module;

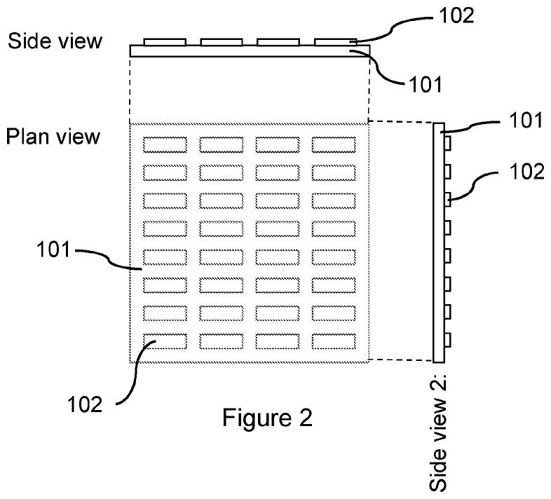

FIG. 2 is a plan and side view of a first substrate and electrical interconnect pattern in a standard thermoelectric module;

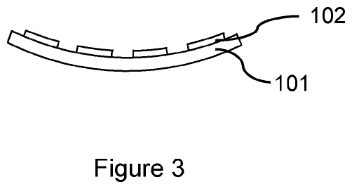

FIG. 3 is a side view of a first substrate and electrical interconnect pattern in a standard thermoelectric module exhibiting bowing after a temperature change;

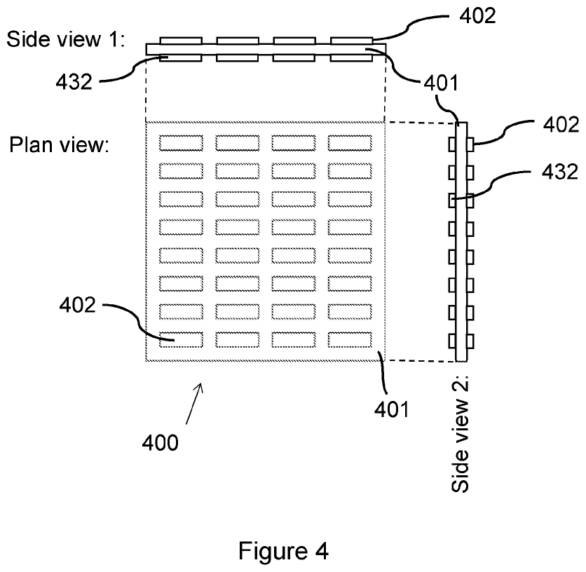

FIG. 4 is a plan and side view of a first substrate with an electrical interconnect pattern on a first face of the first substrate and a plurality of regions of metallic material disposed in a pattern on a second face opposite the first face of the first substrate;

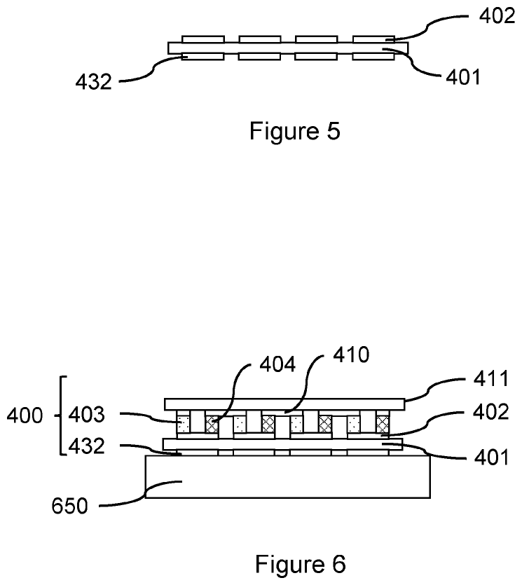

FIG. 5 is a side view of the arrangement of FIG. 4 after a temperature change;

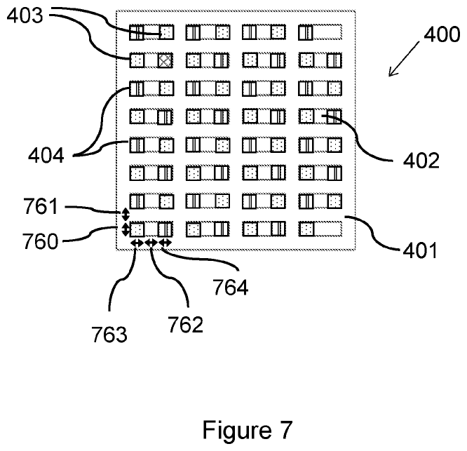

FIG. 6 is a side view of a thermoelectric module with an electrical interconnect pattern on a first face of the first substrate and a plurality of regions of metallic material disposed in a pattern on a second face opposite the first face of the first substrate when interfaced with a mounting plate;

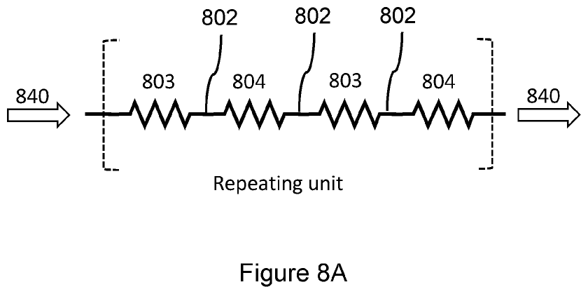

FIG. 7 is a plan view of a first substrate, electrical interconnects and thermoelectric elements in a standard thermoelectric module;

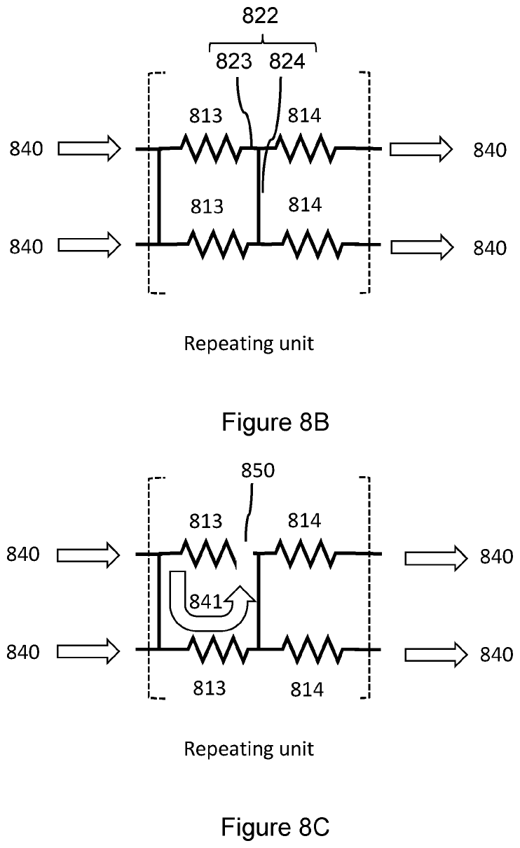

FIG. 8A is a schematic of the electrical connections of a standard thermoelectric module;

FIG. 8B is a schematic of the electrical connections of a thermoelectric module according to an embodiment;

FIG. 8C is a schematic of the electrical connections of a thermoelectric module as shown in 8B after a failure has occurred;

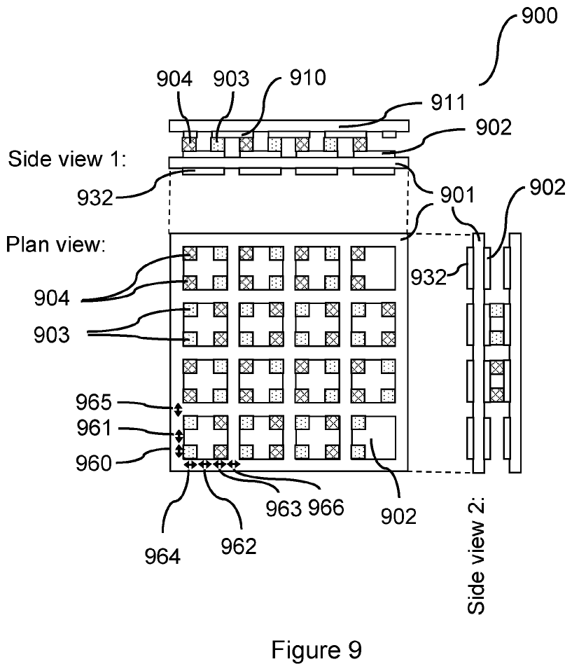

FIG. 9 is a plan and side view of a thermoelectric module according to an embodiment; and

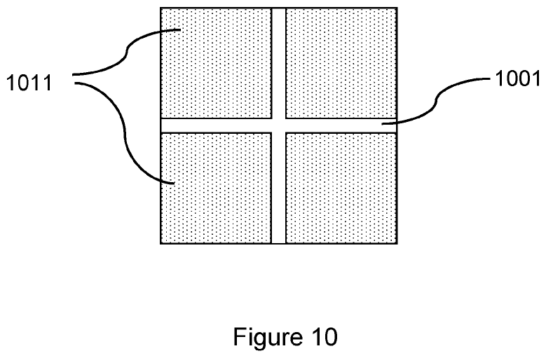

FIG. 10 is a plan view of the first and second substrates according to an embodiment.

An example of a standard thermoelectric module 100 as is known in the art is shown in FIG. 1. The thermoelectric module 100 comprises a first electrically-insulating substrate 101 and a first plurality of electrical interconnects 102 disposed on a first face of the first substrate 101. A second plurality of electrical interconnects 110 is disposed on a first face of a second electrically-insulating substrate 111. The second substrate 111 is shown as transparent for clarity. The electrical interconnects 102, 110 connect alternating n-type thermoelectric elements 104 and p-type thermoelectric elements 103 in series, thereby forming a string of electrically-connected thermocouples. External wires 120, 121 allow external electrical connection. Such a thermoelectric module 100 may be electrically connected to an external power source (not shown) to provide electrical cooling or heating, or be thermally connected across a temperature difference between the substrates 101, 111 to generate electrical power.

FIG. 2 shows a plan and two side views of the first electrically-insulating substrate 101 and the first plurality of electrical interconnects 102 disposed on the first face of the first substrate 101.

FIG. 3 shows an example of the warping that can occur when the first substrate 101 and the first plurality of electrical interconnects 102 disposed thereon are subject to a temperature change resulting in a warped first substrate and warped electrical interconnects thereon. The example here is geometrically exaggerated for clarity, and shows an example of the warping when a temperature reduction from the bonding temperature of the first plurality of electrical interconnects 102 and the first substrate 101 occurs, where the thermal expansion coefficient of the first plurality of electrical interconnects 102 is higher than the thermal expansion coefficient of the first substrate 101.

FIG. 4 shows a portion of a thermoelectric module 400, specifically a first electrically-insulating substrate 401 with a first plurality of electrical interconnects 402 disposed in a pattern on a first surface of the first electrically-insulating substrate 401. A plurality of regions of metallic material 432 is disposed in a pattern on a second surface of the first electrically-insulating substrate 401. The second surface of the first electrically-insulating substrate 401 is opposite the first surface of the first electrically-insulating substrate 401. The first plurality of electrical interconnects 402 are joined to thermoelectric elements in a subsequent module assembly operation. In some embodiments, the patterns on the first and second faces of the first substrate may be substantially similar or identical.

FIG. 5 shows the resulting geometry change to the first substrate 401, the first plurality of electrical interconnects 402 and the regions of metallic material 432 when a temperature change is applied thereto. It can be seen that the use of substantially identical patterns on both faces of the substrate 401 drastically reduces the warping, due to the balance forces from the two patterns. Note that the first substrate 401, and the first plurality of electrical interconnects 402 and the regions of metallic material 432 will still change in length, width and height due to thermal expansion or contraction, but the warping, which may be of larger scale, is reduced or even avoided.

The patterns on both faces of the first substrate may differ in size, shape and the area fraction of the substrate. The larger the difference in area fraction of the substrate covered by the two patterns, the less the warping will be reduced from only having the first pattern (i.e. the pattern formed by the first plurality of electrical interconnects).

FIG. 6 shows a side view of the thermoelectric module 400 comprising the first electrically-insulating substrate 401 with the first plurality of electrical interconnects 402 disposed in a first pattern on the first face of the first electrically-insulating substrate 401 and the regions of metallic material 432 disposed in a third pattern on the second face of the first electrically-insulating substrate 401. A second plurality of electrical interconnects 410 is disposed in a second pattern on a first face of a second electrically-insulating substrate 411. Alternating n-type thermoelectric elements 404 and p-type thermoelectric elements 403 are disposed between the first electrically-insulating substrate 401 and the second electrically-insulating substrate 411. The electrical interconnects 402, 410 connect the n-type thermoelectric elements 404 and the p-type thermoelectric elements 403 in series, thereby forming a string of electrically connected thermocouples. The thermoelectric module 400 is mounted to an external system by a mounting plate 650 connected to the regions of metallic material 432 disposed on the second face of the first electrically-insulating substrate. The mounting plate 650 may comprise or be part of: an item requiring heating or cooling; a thermally conductive block; or a heat transfer device such as a heat sink or a heat exchanger. It can be seen that the use of the regions of metallic material 432 reduces the interface area between the thermoelectric module 400 and the mounting plate 650. This reduction in area increases the thermal resistance of this interface. This can result in a reduction in performance of the thermoelectric module, providing a barrier to heat flow for a thermoelectric heat pump and reducing the temperature difference across the module for a thermoelectric generator.

FIG. 7 shows a plan view of part of the thermoelectric module 400, showing the first electrically-insulating substrate 401, the first plurality of electrical interconnects 402 disposed on the first face of the first electrically-insulating substrate 401 and alternating n-type thermoelectric elements 404 and p-type thermoelectric elements 403. The length, l of the thermoelectric elements is shown as 760, with a width of the n-type thermoelectric element defined as wn, 764 and the width of the p-type thermoelectric element defined as wp, 763. The spacing between the thermoelectric elements is defined as sv 761 in one direction and sh 762 in the other direction. For the purpose of this example it is assumed that the electrical interconnects line up with the relevant edges of the thermoelectric elements. The fraction of substrate area covered by the interconnects, AF is then given by:

$$AF = \frac{l \times ( wp + sh + wn )}{( l + sv ) \times ( wp + 2 sh + wn )}$$

Using the common simplification, sv=sh=s, wp=wn=l=w

$$AF = \frac{w \times ( 2 w + 2 )}{( w + s ) \times ( 2 w + 2 s )} \leq 1$$

It can be seen that increasing w and decreasing s results in a higher AF, but this results in changes in thermoelectric performance and often cost increases due to more thermoelectric material usage, and s typically has a lower limit imposed by manufacturing constraints. Therefore, it is not easy to avoid the extra interface thermal resistance between the thermoelectric module and the mounting plate due to the reduced interface area.

In some embodiments, a thermal interface material such as a grease, paste, putty, pad or graphite sheet may be used to reduce the thermal interface resistance between the thermoelectric module and the mounting plate. A thermal interface material may be used to fill in the gaps between the second electrical interconnects. Thermal interface materials typically may have a thermal conductivity much smaller than that of the substrate and electrical interconnects.

FIG. 8A shows a repeating unit of the typical electrical connections in a thermoelectric module, with the alternating n-type thermoelectric elements' resistance 804 and p-type thermoelectric elements' resistance 803. These are joined by the electrical interconnects 802, allowing current flow 840 to occur along the series-connected string. The series-connected string of the thermoelectric elements means that any break in a thermoelectric element, electrical interconnect or joint between them breaks the electrical circuit, leading to complete module failure as there is no continuous path for the current to flow.

FIG. 8B shows a repeating unit of the electrical connections in a thermoelectric module according to an embodiment, where the n-type thermoelectric elements' resistance 814 and p-type thermoelectric elements' resistance 813 is connected by an electrical interconnect 822. The electrical interconnect 822 connects n and p-type thermoelectric elements in a series-connected string using a first interconnect portion 823, and provides a cross connection to a second series-connected string through a second interconnect portion 824. The current flow in normal operation is shown by 840, with minimal current flow through the cross connection provided by the second interconnect portion 824. In some implementations, the use of two series-connected strings with multiple cross-connections between them may mean that every thermoelectric element of a given type (n-type or p-type) is in parallel with another thermoelectric element of the same type. If any single break in a thermoelectric element, electrical interconnect or joint between them occurs, there is an alternative electrical path around the break. An example is illustrated in FIG. 8C, where a break in the thermoelectric module, depicted by 850, disrupts the current flow from one thermoelectric element to the electrical interconnect. The use of cross connections between the series-connected strings, putting thermoelectric elements in parallel, means that there is an alternative current path, 841. This avoids complete module failure, as current can continue to flow with only a small drop in module performance.

FIG. 9 shows a plan and side view of a thermoelectric module 900. The thermoelectric module 900 comprises a first electrically-insulating substrate 901, a first plurality of electrical interconnects 902 disposed in a first pattern on a first face (the inner face) of the first substrate 901 and regions of metallic material 932 disposed in a third pattern on a second face (the outer face) of the first substrate 901. A second plurality of electrical interconnects 910 is disposed in a second pattern on a first face (the inner face) of a second electrically-insulating substrate 911. The electrical interconnects 902, 910 connect n-type thermoelectric elements 904 and p-type thermoelectric elements 903 in two series-connected strings, with each series-connected string cross-connected to each other, so that every thermoelectric element is electrically in parallel to an adjacent thermoelectric element of the same type. Such a thermoelectric module may be electrically connected to an external power source to provide electrical cooling or heating, or be thermally connected across a temperature difference between the substrates 901, 911 to generate electrical power.

The length, l of the thermoelectric elements is shown as 960, with a width of the n-type thermoelectric element defined as wn, 964 and the width of the p-type thermoelectric element defined as wp, 963. The spacing between thermoelectric elements on the same interconnect is defined as ssv 961 in one direction and ssh 962 in the other direction. The spacing between thermoelectric elements on different interconnects is defined as sdv 965 in one direction and sdh 966 in the other direction. For the purpose of this example it is assumed that the interconnects match to the relevant edges of the thermoelectric elements. The fraction of area covered by the interconnect when using parallelisation, AFP is then given by:

$$AFP = \frac{( 2 l + ssv ) \times ( wp + ssh + wn )}{( 2 l + ssv + sdv ) \times ( wp + ssh + wn + sdh )}$$

Using the common simplification, ssv=ssh=sdv=sdh=s, wp=wn=l=w

$$AFP = \frac{{( 2 w + s )}^{2}}{{( 2 w + 2 s )}^{2}} \leq 1$$

Comparing this area fraction to the case without parallelisation of the TE elements:

$$\frac{AFP}{AF} = \frac{( 2 w + s ) ( w + s )}{( 2 w + 2 s ) ( w )} = \frac{2 {w}^{2} + 3 ws + {s}^{2}}{2 {w}^{2} + 2 ws} > 1$$

This shows that for any positive value of s and w, introducing parallelisation leads to a larger fraction of the area of the first substrate being covered by the first plurality of interconnects. Therefore, with a substantially similar third pattern of regions of metallic material disposed on the second face of the first electrically-insulating substrate, there would be a similar larger area fraction on the second face (the outer face) of the first substrate. This larger area fraction will result in a better thermal contact, giving a lower interface thermal resistance to the mounting plate. Therefore, an advantage of this embodiment is that a first pattern is used to connect thermoelectric elements in parallel, increasing fault tolerance, and the third pattern on the other face of the first substrate is used to minimise warping, with the best results if the first and third patterns are substantially similar on each face, with the requirements on the first pattern for parallelisation increasing the area fraction of the substrate covered by the interconnect, thus reducing the performance loss due the increased thermal interface resistance caused by an area fraction that is less than one.

In some embodiments, the third pattern on the second face (the outer face) of the first substrate may be substantially similar to the first pattern on the first face (the inner face) of the first substrate.

The third pattern may cover a larger area fraction of the substrate than the first pattern. This trades some increased bowing of the first substrate for a lower thermal resistance when connecting the module to an external system by a mounting plate.

FIG. 10 illustrates an embodiment where the first substrate 1001 is a single substrate, but the second substrate has been split into four substrate parts 1011. In other embodiments, more or fewer than four part substrates are provided.

It will be understood that the invention is not limited to the embodiments above-described and various modifications and improvements can be made without departing from the concepts described herein. Except where mutually exclusive, any of the features may be employed separately or in combination with any other features and the disclosure extends to and includes all combinations and sub-combinations of one or more features described herein.

1. A thermoelectric module comprising:
a first electrically-insulating substrate having a first face and a second face opposite the first face, wherein a first plurality of electrical interconnects is disposed in a first pattern on the first face;
a second electrically-insulating substrate spaced from the first electrically-insulating substrate and having a first face facing the first face of the first electrically-insulating substrate, wherein a second plurality of electrical interconnects is disposed in a second pattern on the first face of the second electrically-insulating substrate;
a plurality of thermoelectric elements comprising n-type thermoelectric elements and p-type thermoelectric elements disposed between the first electrically-insulating substrate and the second electrically-insulating substrate, wherein each thermoelectric element extends from one of the first plurality of electrical interconnects to one of the second plurality of electrical interconnects, wherein the thermoelectric elements are arranged to form a first series-connected string of alternating n-type and p-type thermoelectric elements and a second series-connected string of alternating n-type and p-type thermoelectric elements and at least one of the n-type or p-type thermoelectric elements in the first series-connected string is electrically connected in parallel with one of the thermoelectric elements of the same type (n-type or p-type) in the second series-connected string; and
one or more regions of metallic material are disposed in a third pattern on the second face of the first electrically-insulating substrate.

2. The thermoelectric module according to claim 1, wherein at least one pair of thermoelectric elements comprising a thermoelectric element in the first series-connected string and a thermoelectric element of the same type in the second series-connected string that are electrically connected in parallel is disposed at or in the vicinity of a corner or corner region of the first electrically-insulating substrate and/or the second electrically-insulating substrate.

3. The thermoelectric module according to claim 1, wherein at least one pair of thermoelectric elements comprising a thermoelectric element in the first series-connected string and a thermoelectric element of the same type in the second series-connected string that are electrically connected in parallel is disposed at or in the vicinity of an edge or edge region of the first electrically-insulating substrate and/or the second electrically-insulating substrate.

4. The thermoelectric module according to claim 17, wherein every thermoelectric element in the first series-connected string is electrically connected in parallel with one of the thermoelectric elements of the same type in the second series-connected string.

5. The thermoelectric module according to claim 1, wherein one or more of the thermoelectric elements in the first series-connected string is not electrically connected in parallel with one of the thermoelectric elements of the same type in the second series-connected string.

6. The thermoelectric module according to claim 1, wherein the third pattern is similar to or substantially the same as the first pattern.

7. The thermoelectric module according to claim 1, wherein the third pattern has an area fraction on the second face of the first electrically-insulating substrate that is smaller than, the same as or larger than an area fraction of the first pattern on the first face of the first electrically-insulating substrate.

8. The thermoelectric module according to claim 1, wherein one or more regions of metallic material are disposed in a fourth pattern on a second face opposite the first face of the second electrically-insulating substrate.

9. The thermoelectric module according to claim 8, wherein the fourth pattern is similar to or substantially the same as the second pattern.

10. The thermoelectric module according to claim 8, wherein the fourth pattern has an area fraction on the second face of the second electrically-insulating substrate that is smaller than, the same as or larger than an area fraction of the second pattern on the first face of the second electrically-insulating substrate.

11. The thermoelectric module according to claim 1, wherein at least one of the first plurality of electrical interconnects and/or at least one of the second plurality of electrical interconnects is connected to two or more n-type thermoelectric elements and two or more p-type thermoelectric elements.

12. The thermoelectric module according to claim 11, wherein at least one of the first plurality of electrical interconnects and/or at least one of the second plurality of electrical interconnects is/are rectangular, e.g. square, in shape, and connected to two n-type thermoelectric elements and two p-type thermoelectric elements with the thermoelectric elements being connected to the electrical interconnect(s) at or close to the corners of the rectangular, e.g. square, electrical interconnect(s).

13. The thermoelectric module according to claim 1, wherein the first substrate and/or the second substrate is/are made up of two or more substrate parts.

14. The thermoelectric module according to claim 13, wherein the first substrate and/or the second substrate is/are made up of at least two rows of substrate parts.

15. The thermoelectric module according to claim 13, wherein the first substrate and/or the second substrate is/are made up of up to five rows of substrate parts.

16. The thermoelectric module according to claim 13, wherein the first substrate and/or the second substrate is/are made up of at least two columns of substrate parts.

17. The thermoelectric module according to claim 13, wherein the first substrate and/or the second substrate is/are made up of up to five columns of substrate parts.

18. The thermoelectric module according to claim 1, further connected to an external system by a mounting plate connected to the third pattern on the second surface of the first electrically-insulating substrate.

19. The thermoelectric module according to claim 18, wherein the mounting plate comprises or is a part of: an item requiring heating or cooling; a thermally conductive block; or a heat transfer device such as a heat sink or a heat exchanger.

20. A method of manufacturing a thermoelectric module comprising:
providing a first electrically-insulating substrate having a first face and a second face opposite the first face, wherein a first plurality of electrical interconnects is disposed in a first pattern on the first face and one or more regions of metallic material are disposed in a third pattern on the second face of the first electrically-insulating substrate;
providing a second electrically-insulating substrate having a first face, wherein a second plurality of electrical interconnects is disposed in a second pattern on the first face of the second electrically-insulating substrate;
providing a plurality of thermoelectric elements comprising n-type thermoelectric elements and p-type thermoelectric elements;
connecting a first end of each thermoelectric element to one of the first plurality of electrical interconnects;
connecting a second end of each thermoelectric element to one of the second plurality of electrical interconnects;
wherein the thermoelectric elements are arranged to form a first series-connected string of alternating n-type and p-type thermoelectric elements and a second series-connected string of alternating n-type and p-type thermoelectric elements and at least one of the n-type or p-type thermoelectric elements in the first series-connected string is electrically connected in parallel with one of the thermoelectric elements of the same type (n-type or p-type) in the second series-connected string.
